(19) United States
(12) Patent Application Publication
(10) Pub. No.: US 2012/0098395 A1
(43) Pub. Date: Apr. 26, 2012

(54) IMAGE FORMING APPARATUS

(75) Inventor: Akira SATO, Shizuoka-ken (JP)

(73) Assignees: Toshiba Tec Kabushiki Kaisha, Tokyo (JP); Kabushiki Kaisha Toshiba, Tokyo (JP)

(21) Appl. No.: 13/281,307

(22) Filed: Oct. 25, 2011

Related U.S. Application Data
(60) Provisional application No. 61/406,987, filed on Oct. 26, 2010.

(51) Int. Cl. H05K 5/02; H05K 7/20

(52) U.S. Cl. 312/236; 312/223.1

(57) ABSTRACT

Provided is an image forming apparatus of which installation can be performed easily.

The image forming apparatus includes a main body of the apparatus, a protrusion portion which horizontally protrudes to the outside of a projection portion in which the main body is projected in the vertical direction with respect to the bottom of the main body from the upper part of the main body, on the rear side of the image forming apparatus, and an adjuster which is an adjuster that adjusts a gap between an installation surface of the image forming apparatus and main body, and has an operation unit which is disposed to the outside of the projection portion of the protrusion portion in the horizontal direction, and performs an operation of adjusting the gap at the upper part of the top face of the protrusion portion.

### CROSS-REFERENCE TO RELATED APPLICATION

This application is based upon and claims the benefit of priority from U.S. provisional application 61/406,987, filed on Oct. 26, 2010, the entire contents of which are incorporated herein by reference.

### FIELD

Embodiments described herein relate to horizontal adjustment, height adjustment, and fixing of an image forming apparatus.

### BACKGROUND

A large-sized image forming apparatus such as an MFP (Multi-Function Peripheral) is normally installed on a stable installation surface such as a floor. In the related art, there is provided an image forming apparatus in which adjusters which adjust the levelness of the image forming apparatus and fix the apparatus are attached to four corners of the image forming apparatus, at the bottom thereof, in order to form images with good quality. When installing the image forming apparatus, it is possible to install the apparatus to be horizontal by changing the length thereof by rotating the adjusters.

On the other hand, when installing the image forming apparatus, normally the backside thereof is positioned along a wall, or sometimes it may be installed at the corner of the wall. When installing the image forming apparatus along the corner, the adjuster which is positioned at the corner of a rear surface side of the image forming apparatus is not easy to adjust, since it is at the bottom of the image forming apparatus.

### DESCRIPTION OF THE DRAWINGS

FIG. 1 is a diagram which shows an appearance of an image forming apparatus.

FIG. 2 is a schematic diagram which shows only a base portion of the image forming apparatus.

FIG. 3 is a side view which shows only the base portion of the image forming apparatus.

FIG. 4 is a side view which shows only the base portion of the image forming apparatus.

### DETAILED DESCRIPTION

According to an embodiment of the disclosure, there is an image forming apparatus which includes a main body of the apparatus, a protrusion portion, and adjusters. The protrusion portion horizontally protrudes to the outside of a projection portion in which the main body of the image forming apparatus is projected in the vertical direction with respect to the bottom of the main body of the apparatus from the upper part of the main body of the image forming apparatus, on the rear side of the image forming apparatus. The adjuster adjusts the gap between an installation surface of the image forming apparatus and main body of the apparatus, and has an operation unit which is disposed to the outside of the projection portion of the protrusion portion in the horizontal direction, and performs an operation of adjusting the gap at the upper part of the top face of the protrusion portion.

Hereinafter, an embodiment of the disclosure will be described with reference to drawings.

### First Embodiment

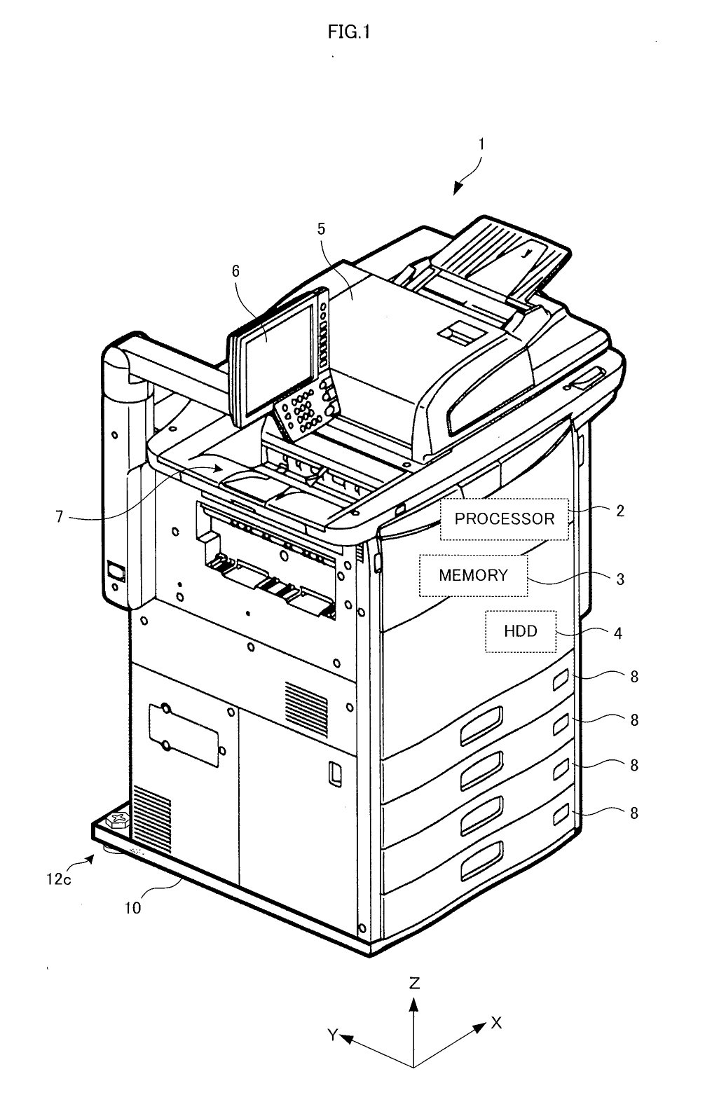

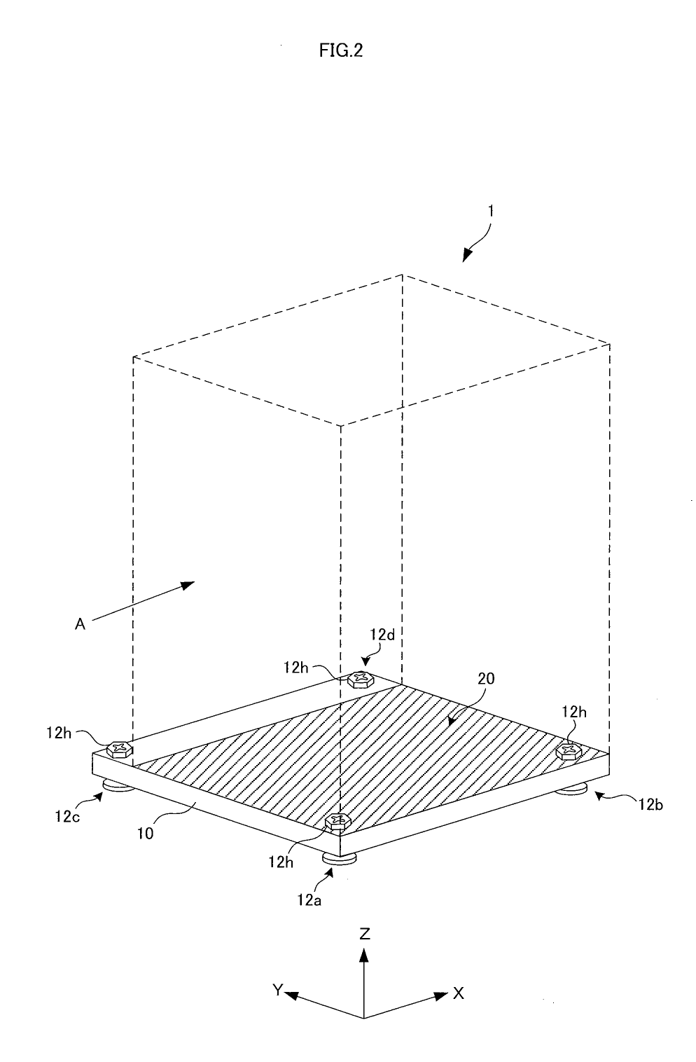

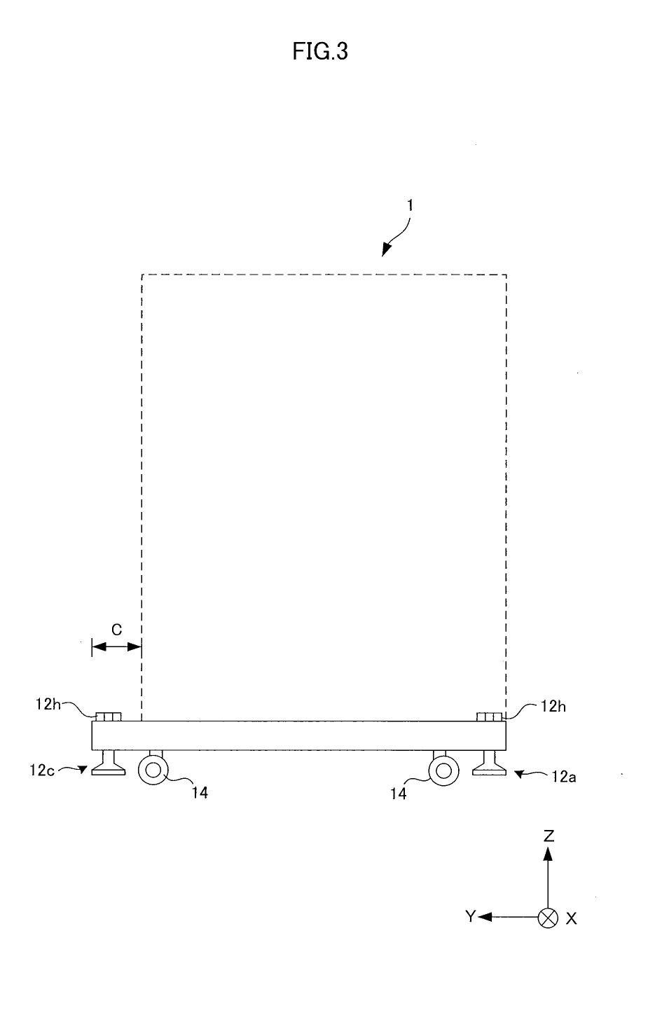

FIG. 1 is a diagram which shows an appearance of an image forming apparatus 1. FIGS. 2 and 3 are schematic diagrams which show only a base portion 10 of the image forming apparatus 1. FIG. 2 is a perspective view, and FIG. 3 is a diagram which is seen from the direction of an arrow A (side surface) in FIG. 2. The image forming apparatus 1 is an MFP (Multi-Function Peripheral) which includes functions of a printer, a copy machine, a scanner, a facsimile, and the like. The image forming apparatus 1 includes a processor 2, a memory 3, an HDD (Hard Disk Drive) 4, a read unit 5, an operation panel 6, a discharge tray 7, a sheet feeding cassette 8, a base 10, and the like.

The processor 2 controls various processes in the image forming apparatus 1. As the processor 2, a CPU (Central Processing Unit), an MPU (Micro Processing Unit) which can execute the same calculation as that of the CPU, or the like, are used. In addition, a part of the function of the image forming apparatus 1 may be executed by an ASIC (Application Specific Integrated Circuit) as a processor.

The memory 3 is a semiconductor memory. The memory 3 includes a ROM (Read Only Memory) which houses a control program of the processor 2, a RAM (Random Access Memory) which provides a temporary work area for the processor 2, or the like.

An HDD 4 is an auxiliary memory unit which stores a variety of information in the MFP 1. As the auxiliary memory unit, for example, a flash memory, an SSD (Solid State Drive), or a magnetic disk other than an HDD, or the like.

The read unit 5 reads images on the original document.

The operation panel 6 is provided with a touch panel or an operation key with which the execution of various processes with respect to the image forming apparatus 1 is instructed, or an input of an operation which sets conditions of the processing can be performed. In addition, the setting contents for the operational situation or conditions settings of the image forming apparatus 1 are displayed on the touch panel.

The discharge tray 7 is a tray to which a sheet, on which images are formed, is discharged.

The sheet feeding cassette 8 receives the sheet on which images are formed. The image forming apparatus 1 includes four sheet feeding cassettes 8 which can receive a variety of sizes of sheets.

The image forming apparatus 1 further includes an image forming unit, or the like, which forms images on the sheet which is supplied from the sheet feeding cassette 8. The image forming unit is formed of a process unit which forms a toner image on a photoconductor, a transfer unit which transfers the toner image which is formed in the process unit to the sheet, a fixing unit which fixes to the sheet the toner image transferred to the sheet, or the like.

The base 10 is a pedestal on which the main body of the image forming apparatus 1 is placed. As shown in FIGS. 2 and 3, adjusters 12a to 12d and a caster 14 are attached to the four corners of the base 10.

The adjusters 12a to 12d are members which fix the image forming apparatus 1 to an installation surface, such as a floor, and can adjust the gap between the bottom of the image forming apparatus 1 (the bottom of the base 10, in a case of the image forming apparatus 1 of the embodiment) and the installation surface of the image forming apparatus 1. The adjusters 12a to 12d according to the embodiment have a screw thread in the shaft, and it is possible to adjust the gap between the apparatus and the installation surface of the apparatus by changing the length which extends from the lower surface of the base 10 by being rotated. It is possible to fix the image forming apparatus 1 so as not to move, by making the caster 14 float from the surface of the floor by making the length from the lower surface of the base 10 to the front end of the adjusters 12a to 12d longer than the length from the bottom of the base 10 to the installation surface (the floor) of the caster 14. In addition, it is possible to install the image forming apparatus 1 to be level by adjusting the levelness when the length of each adjuster 12a to 12d is adjusted.

The caster 14 is a wheel for moving the image forming apparatus 1. The caster 14 may be arranged in numbers which allow movement of the image forming apparatus 1, and according to the embodiment, four casters are arranged in the vicinity of the four adjusters 12a to 12d and to the inside of the adjusters at the bottom of the base 10.

In addition, the base 10 in the embodiment protrudes to a rear side surface (Y axis direction in FIGS. 1 to 3) of a projection portion 20 which is projected in the vertical direction with respect to a surface (a horizontal surface) on the base 10 from the upper part of the image forming apparatus 1 which is placed on the base 10 (a part which protrudes from the projection portion 20 of the base 10 corresponds to the protruding portion). The projection portion 20 is a region which is filled with diagonal lines on the base 10 in FIG. 2.

In addition, to simplify the description, in FIG. 2, a part on the base of the image forming apparatus 1 (a main body of the apparatus) is expressed as a simple rectangular body, and the projection portion 20 is also shown as a rectangular shape, however, in practice, they have shapes which correspond to the structure and shape of the image forming apparatus 1. In the image forming apparatus 1 shown in FIG. 1, the read unit 5 and the discharge tray 7 protrude to the lateral side (the X axis direction) of a housing on the lower part of them, or an exterior plate of the front surface including sheet feeding cassettes 8 protrudes to the outside of the base 10, on the front surface of the image forming apparatus 1. Accordingly, in practice, the projection portion 20 expands up to a range which is protruding as described above, in the horizontal surface on the base 10.

In addition, the adjusters 12c and 12d on the rear surface side of the image forming apparatus 1 are arranged to a position further to the rear side of the projection portion 20. According to the embodiment, the adjusters 12c and 12d are disposed further to the rear side of the projection portion 20, when they are disposed at a portion which protrudes further to the rear surface side of the image forming apparatus 1 than the projection portion 20.

In addition, since the adjusters 12a to 12d in the embodiment have a cross-shaped recess as an operation unit on a head portion 12 which is shown on the base 10, it is possible to adjust the length of the adjusters by rotating the adjusters using a tool, such as a Phillips screwdriver, from the upper part of the image forming apparatus 1. That is, the adjusters 12a to 12d according to the embodiment are formed with the operation unit which can perform an operation of adjusting the length of the adjusters on the upper part of the upper surface of the base 10. In addition, the adjusters 12a to 12d can be rotated by directly rotating a ground-touching portion to the installation surface, or may be rotated by inserting a tool such as a wrench to the lower part of the base 10.

According to the above described embodiment, the adjusters 12c and 12d on the rear surface side of the image forming apparatus 1 are provided further to the rear surface side of the projection portion 20 of the image forming apparatus 1 with respect to the horizontal surface on the base 10. In addition, since the operation unit which can adjust the adjusters 12c and 12d is formed on the upper side of the top surface of the protrusion portion of the base 10, it is possible to adjust the adjusters from the upper part of the image forming apparatus 1. Accordingly, it is possible to adjust the adjusters, even when the adjusters 12c and 12d are positioned at a corner portion of a wall when the image forming apparatus 1 is installed at the corner of the wall. For example, even if the image forming apparatus 1 is installed so that the adjuster 12d is positioned at the corner of the wall, it is possible to perform adjustment by rotating the adjuster 12d from the upper part of the image forming apparatus 1, using a Phillips screwdriver with a long shaft.

On the other hand, in the adjuster of an ordinary image forming apparatus, it is necessary to adjust the length thereof by rotating the adjuster using a wrench or the like which is inserted from the lateral side. For this reason, when the image forming apparatus is installed close to the corner of a wall, it may be difficult to adjust the length of the adjuster which is positioned at the corner.

In addition, the adjusters 12a and 12b on the front surface side of the image forming apparatus 1 are also shown as the adjusters with the cross-shaped recess on the head portion, in FIGS. 2 and 3 as described in the embodiment, however, the adjusters on the front surface side may be adjusters which can be rotated using a wrench or the like which is inserted from the lateral side, as in the related art.

Further, as a configuration of the operation unit which rotates the adjusters from the upper part, a configuration in which the head portion includes the cross-shaped recess is shown, however, the configuration is not limited to this. For example, the recess on the head portion may have a shape of a minus sign or a polygonal shape such as a hexagon, and may be a bolt with a polygonal shape on the head portion. In addition, the operation unit may be a unit having a knob such as a wing bolt. Other than those, the operation unit may have any structures, as long as it is a structure which can rotate the adjusters from the upper part of the image forming apparatus.

In addition, in the embodiment, the entire rear surface side of the image forming apparatus 1 on the base 10 has a shape of further protruding to the rear surface side of the apparatus than the projection portion 20, however, the configuration is not limited to this. It may be a configuration in which a portion which is necessary to arrange the adjusters 12c and 12d, is protruded to the rear surface side of the image forming apparatus 1. By adopting such a structure, it is possible to realize a miniaturization and light weight of the base 10, and to improve ventilation of the apparatus on the rear surface side and the bottom side, compared to a case where the entire body is protruded. Further, in this manner, when only the portion to which the adjusters 12c and 12d are disposed is protruded, a vent hole which is disposed at the rear surface of the image forming apparatus 1 may be arranged in a range in which the base 10 does not protrude in the left and right direction (the X axis direction in FIG. 1) of the apparatus. In this case, if the vent hole is an exhaust outlet, it is possible to prevent a flow of air which is discharged from the rear side to the bottom of the apparatus from being disturbed due to the protrusion portion. Further, if the vent hole is an intake port, it is possible to prevent the flow of air from the bottom side of the apparatus to the intake port on the rear surface from being disturbed due to the protrusion portion.

In addition, according to the embodiment, the adjusters 12c and 12d on the rear surface side are set to be disposed further to the rear surface side than the projection portion 20 with respect to the horizontal surface on the base 10 of the image forming apparatus 1, however, the configuration is not limited to this. Since it is preferable that only the adjuster be rotated from the upper part when the image forming apparatus 1 is installed close to the corner of the wall, the adjuster may be disposed further to the side surface side of the image forming apparatus 1 than the projection portion 20 to the horizontal surface on the base 10, or at the outside on an extended line of a diagonal line of the projection portion 20 in addition to the rear surface side. That is, if it is possible to adjust the adjusters from the upper part of the image forming apparatus 1, the adjuster may be arranged at a position which is in the vicinity of the corner portion of the image forming apparatus 1, and disposed to the outside of the projection portion 20.

In addition, according to the embodiment, a configuration in which the image forming apparatus 1 is placed on the base 10 is described, however, it is not necessarily required to be a structure in which the main body of the apparatus is supported by the base 10. When an independent member such as the base 10 is not provided as a member for supporting the main body of the apparatus, apart to which the adjusters 12c and 12d on the rear surface side of the image forming apparatus 1 are attached may be protruded to the rear surface side of the projection portion 20, and the adjusters 12c and 12d may be attached to the protruding portion.

In addition, according to the embodiment, an MFP is exemplified as an image forming apparatus, however it is not limited thereto. The image forming apparatus may be other image forming apparatuses such as a copy machine, a printer, and the like.

### Second Embodiment

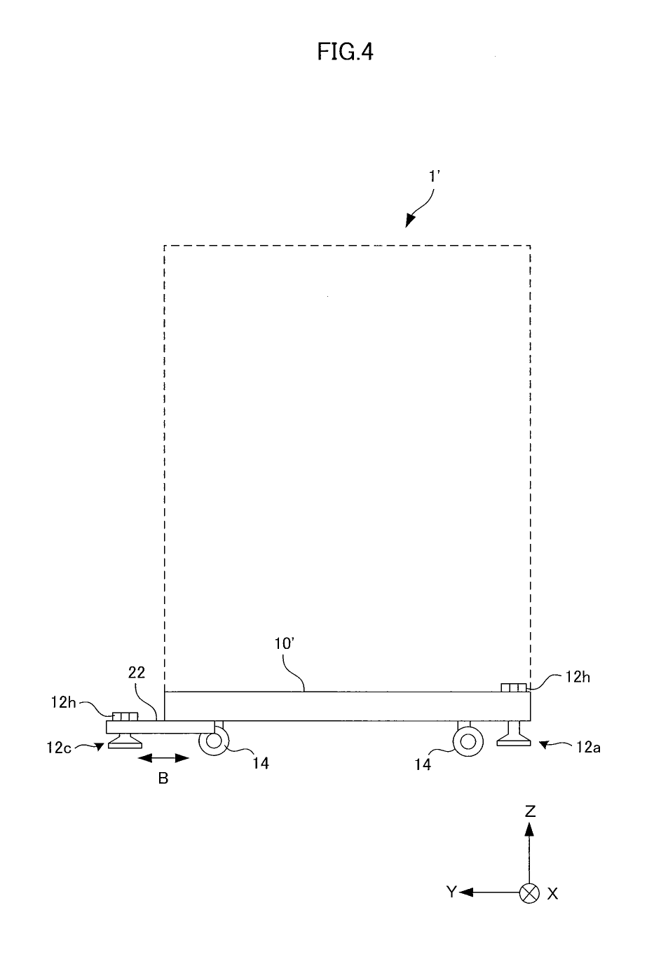

A second embodiment will be described. FIG. 4 is a side view of only a base portion 10′ of an image forming apparatus 1′ according to the embodiment. In the embodiment, different from the first embodiment, the size of the base 10′ of the image forming apparatus 1′ has the same size as the bottom portion of a main body of the apparatus which is placed on the base 10′. On the other hand, the image forming apparatus 1′ according to the embodiment includes a slide portion 22 which is attached to the base 10′ movably in the direction of both arrows B along a Y axis direction. Adjusters 12c and 12d on the rear surface side are respectively attached to the slide portion 22.

In detail, as described above, the base 10′ according to the embodiment is a pedestal of the same size as of the bottom portion of the main body of the apparatus which is placed on the base 10′ different from the first embodiment. In addition, in the base 10′, the slide portion 22 which can slide is disposed at the rear surface side of the image forming apparatus 1′ with respect to the base 10′. The slide portion 22 is attached to the base 10′ using a member which can slide, for example, a slide rail or the like. As described above, the slide portion 22 is able to slide in both direction of the arrow B, that is, in the front and rear direction of the image forming apparatus 1′.

The slide portion 22 can move the adjusters 12c and 12d, which are installed in the slide portion 22, to a position on the rear side surface of a projection portion 20 with respect to a horizontal surface on the base 10′ of the image forming apparatus 1′. It is possible to access the adjusters 12c and 12d from the upper part of the image forming apparatus 1′, by moving the adjusters 12c and 12d to the rear surface side of a range of the projection portion 20 using the slide mechanism.

Therefore, according to the second embodiment, similarly to the first embodiment, it is possible to simply adjust the length of the adjuster by rotating the adjuster from the upper part of the image forming apparatus 1′, even if the image forming apparatus 1′ is installed close to a wall, particularly to a corner portion of a wall.

### Third Embodiment

A third embodiment will be described. An image forming apparatus 1 according to the third embodiment has a configuration in which a base 10 is extended to a rear surface side of a projection portion 20, similarly to the first embodiment. In addition, the length of a protrusion from a position of the rear surface of the image forming apparatus 1 of the base 10, is the length which is necessary between the apparatus and the wall on the rear side or the like, in order to secure ventilation in the rear surface of the image forming apparatus 1.

Generally, the image forming apparatus 1 includes a vent hole on the rear surface, such as an exhaust outlet for discharging air or an air supply port for taking in air, in order to cool various devices which perform image forming processing or image read processing. In addition, in order to secure ventilation for appropriately discharging or taking in the air, a predetermined gap (hereinafter, the predetermined gap is also referred to as a gap for ventilation) to be secured between the rear surface of the image forming apparatus 1 and a hindrance such as a wall disturbing the ventilation, is set.

Since the base 10 according to the embodiment protrudes to the rear surface side of the image forming apparatus 1, the adjusters 12c and 12d can be adjusted from the upper part, however the length of the protrusion (the length shown by both arrows C in FIG. 3) is set to the length of the gap for ventilation.

Accordingly, when installing the image forming apparatus 1 according to the embodiment, for example, the distance between the rear surface portion of the apparatus and the wall does not become shorter than the length of the protrusion from a position at the rear surface of the base 10, even when the image forming apparatus 1 is installed so that the rear surface of the apparatus is close to the wall. Accordingly, according to the embodiment, it is possible to adjust the adjusters 12c and 12d on the rear surface side from the upper part, and reliably secure a gap for ventilation to be secured between the rear surface of the image forming apparatus 1 and the wall.

In addition, in the embodiment, the base 10 is described to be protruded by a gap for ventilation, from a position of the rear surface, however, the configuration is not limited thereto. For example, the base 10 may have a shape protruding to the rear surface side, for a portion in which the adjusters 12c and 12d are arranged only, and the protruding length thereof may be the length of about a gap for ventilation.

Further, in the embodiment, the protruding length of the base 10 from the rear surface of the image forming apparatus 1 is set to the length of about the gap for ventilation. However, the protruding portion of the base 10 may protrude by at least the gap for ventilation, and may protrude longer than the gap for ventilation.

In addition, as described in the second embodiment, in a type in which the adjusters 12c and 12d are respectively attached to the slide portion 22, for example, the distance from the front end of the slide portion 22 to the rear surface of the image forming apparatus 1 may be extended by at least a gap for ventilation. Even in this configuration, if the image forming apparatus 1 is installed in a state where the slide portion 22 is extended, it is possible to adjust the adjusters 12c and 12d from the upper part while securing the gap for ventilation of the image forming apparatus 1.

As described above, according to the technology described in the specification, it is possible to provide an image forming apparatus which can be installed easily.

While certain embodiments have been described, these embodiments have been presented by way of example only, and are not intended to limit the scope of invention. Indeed, the novel apparatus and methods described herein may be embodied in a variety of other forms; furthermore, various omissions, substitutions and changes in the form of the apparatus and methods described herein may be made without departing from the spirit of the inventions. The accompanying claims and their equivalents are intended to cover such forms or modifications as would fall within the scope and spirit of the inventions.

What is claimed is:

1. An image forming apparatus comprising:
a main body of the image forming apparatus;
a protrusion portion which horizontally protrudes to the outside of a projection portion in which the main body of the image forming apparatus is projected in the vertical direction with respect to the bottom of the main body of the apparatus from the upper part of the main body of the image forming apparatus, on the rear side of the image forming apparatus; and
an adjuster which adjusts a gap between an installation surface of the image forming apparatus and the main body of the apparatus, and has an operation unit which is disposed to the outside of the projection portion of the protrusion portion in the horizontal direction, and performs an operation of adjusting the gap at the upper part of the top face of the protrusion portion.

2. The apparatus according to claim 1, further comprising a base which supports the main body of the apparatus,
wherein the protrusion portion is a horizontally expanded portion to the outside of the projection portion of the base.

3. The apparatus according to claim 1,
wherein the protrusion portion protrudes to a position which is separated from the main body of the apparatus, by at least a space which is preset to secure ventilation, in the rear surface side of the image forming apparatus.

4. The image forming apparatus according to claim 3,
wherein a vent hole for ventilation between the inside and outside of the main body of the apparatus is disposed at the rear surface of the main body of the apparatus.

5. The apparatus according to claim 1,
wherein the protrusion portion horizontally protrudes to the outside of the projection portion by sliding in an outside direction of the main body of the apparatus.

6. The apparatus according to claim 1,
wherein the operation unit is a cross-shaped, a minus sign-shaped, or a polygonal recess, or a polygonal head portion or a grippable knob.

7. The apparatus according to claim 1, further comprising:
a front surface side adjuster which has an operation unit which performs an operation of adjusting a gap between the bottom surface of the main body of the apparatus and an installation surface of the image forming apparatus, from the lateral side, and is disposed at the front surface side of the image forming apparatus.
